(19) United States
(12) Patent Application Publication
(10) Pub. No.: US 2006/0246615 A1
(43) Pub. Date: Nov. 2, 2006

(54) Method of manufacturing vertical cavity surface emitting laser

(75) Inventors: Wei Chang, San Chung City (TW); Yi-Te Chen, San Chung City (TW)

Correspondence Address: TROXELL LAW OFFICE PLLC, SUITE 1404, 5205 LEESBURG PIKE, FALLS CHURCH, VA, 22041, US

(73) Assignee: Unity Opto Technology Co., Ltd.

(21) Appl. No.: 11/115,285

(22) Filed: Apr. 27, 2005

(51) Int. Cl. H01L 21/00

(52) U.S. Cl. 438/26; 438/28

(57) ABSTRACT

A method of manufacturing a vertical cavity surface emitting laser is disclosed. The method comprises the steps of: 1. punching one pin of each of a plurality of pin groups mounted on a frame for forming a large-area expanded surface on the pin; 2. coupling a plurality of vertical cavity surface emitting laser diodes to the expanded surfaces of the pins; 3. bonding the vertical cavity surface emitting laser diodes to the other pins by conducting wires; 4. holding the frame on which the vertical cavity surface emitting laser diodes are mounted by a plurality of housings having openings, notches, and mounting chambers to complete the assembly of the vertical cavity surface emitting laser diodes; and 5. cutting off connected portions among the pins to obtain the vertical cavity surface emitting lasers.

### FIELD OF THE INVENTION

The present invention relates to a method of manufacturing a vertical cavity surface emitting laser for simplifying process of assembling the base and substantially reducing production cost, and more particularly to a manufacture method suitable for a vertical cavity surface emitting laser or the like.

### BACKGROUND OF THE INVENTION

In response to the Internet user's demand for the bandwidth, the optical fiber is gradually applied to the local Internet. In the optical fiber system, the signal is converted from electricity to light and from light to electricity by an optical transceiver module for the purpose of delivery. The light source utilized in the existing optical transceiver module is divided into laser diode (LD) and light emitting diode (LED). The laser diode is further divided into edge-emitting laser and surface-emitting laser according to its light emitting manner. The conventional lasers emit the light mostly by way of the edge-emitting manner, and both the vertical cavity surface emitting laser (VCSEL) and the light emitting diode adopt the surface-emitting manner for emitting the light. The light emitting diode provides slow speed and small power output so it is suitable for short distance transmission. The conventional laser diode provides large power output and expensive price so it is mainly applied to long distance transmission. The vertical cavity surface emitting laser provides fast speed and low price so it is suitable for middle and long distance transmission.

However, the conventional light emitting diode emits the light in all directions so there is a need to mount a notched cup on a base to refract and centralize the peripheral light rays for emitting a forward light. Although no notched cup is required in the conventional vertical cavity surface emitting laser, a large-area base is still needed to be provided. As shown in FIG. 1, a large-area base 1 is provided. Three pins are mounted on the bottom surface of the base 1. An assembling device 4, a photo diode 5, and a vertical cavity surface emitting laser diode 6 are mounted on the base 1 in sequence. The base 1 is then held by a housing 2 having a lens 3. In such a structure, the laser light 7 emitted from the vertical cavity surface emitting laser diode 6 can be coupled to an optical fiber 8 through the lens 3.

However, a large-area base on which through holes are formed must be provided in this kind of structure in which the through holes are insulated before being coupled with other pins. Accordingly, a coupling position is supplied for the vertical cavity surface emitting laser diode, and the pins are divided into positive and negative terminals. Thus it is apparent that the major deficiencies of the conventional structure consist in that the large-area base results in the increased production cost, and that the steps for forming the through holes, insulating the through holes, and coupling the pins complicate the manufacture process and indirectly increase the production cost.

Consequently, the present invention provides a method of manufacturing the vertical cavity surface emitting laser suitable for mass production for simplifying the manufacture process and reducing the production cost.

### SUMMARY OF THE INVENTION

It is a main object of the present invention to provide a method of manufacturing the vertical cavity surface emitting laser for simplifying the assembly process of the base and reducing the production cost.

It is another object of the present invention to provide a method of manufacturing the vertical cavity surface emitting laser for mass production.

In order to achieve the aforementioned object, the method of manufacturing the vertical cavity surface emitting laser of the present invention comprises the steps of: 1. punching one pin of each of a plurality of pin groups mounted on a frame for forming a large-area expanded surface on the pin; 2. coupling a plurality of vertical cavity surface emitting laser diodes to the expanded surfaces of the pins; 3. bonding the vertical cavity surface emitting laser diodes to the other pins by conducting wires; 4. holding the frame on which the vertical cavity surface emitting laser diodes are mounted by a plurality of housings having openings, notches, and mounting chambers to complete the assembly of the vertical cavity surface emitting laser diodes; and 5. cutting off connected portions among the pins to obtain the vertical cavity surface emitting lasers.

The aforementioned aspects and advantages of the present invention will be readily clarified in the description of the preferred embodiments and the enclosed drawings of the present invention.

### BRIEF DESCRIPTION OF THE DRAWINGS

FIG. 1 is a schematic cross-sectional view showing the conventional vertical cavity surface emitting laser.

FIG. 2 shows a manufacture process of the present invention.

FIG. 3 is a schematic view showing expanded surfaces of the pins of the present invention.

FIG. 4 is a schematic view of the present invention showing that the frame wirebonded to the vertical cavity surface emitting laser diodes is held by the housing.

FIG. 5 is schematic cross-sectional view showing the vertical cavity surface emitting laser of the present invention.

FIG. 6 is an exploded view of the present invention.

FIG. 7 shows another manufacture process of the present invention.

### DETAILED DESCRIPTION OF THE PREFERRED EMBODIMENT

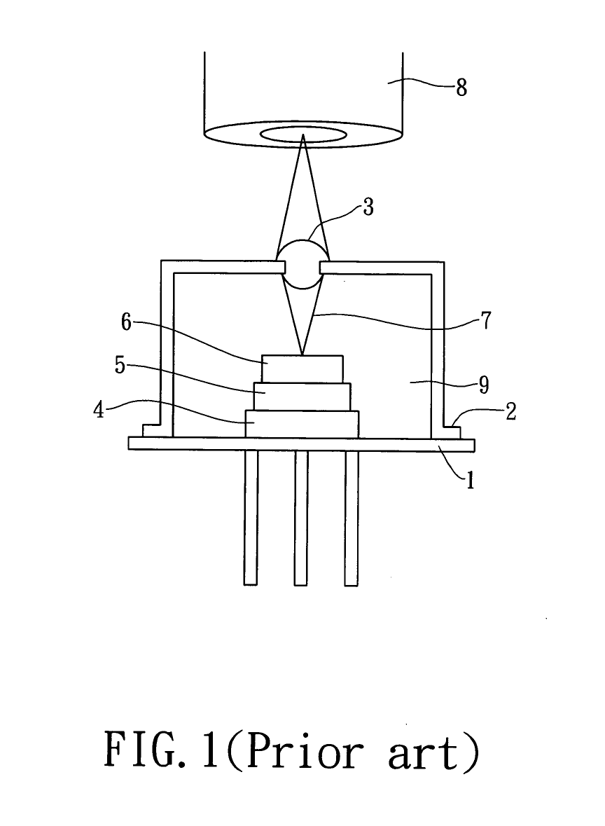

FIG. 1 is a schematic cross-sectional view showing the conventional vertical cavity surface emitting laser. This conventional structure is described above, and its related description is omitted herein.

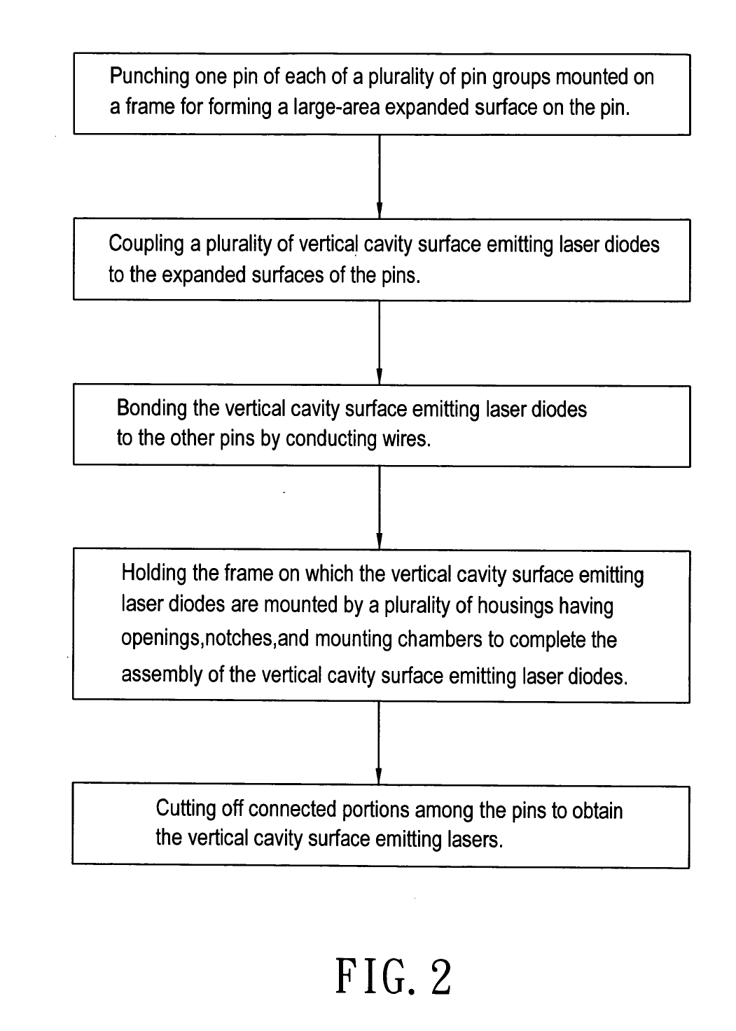

Referring to FIG. 2, a manufacture process of the present invention comprises the steps of:

1. punching one pin of each of a plurality of pin groups mounted on a frame for forming a large-area expanded surface on the pin;

2. coupling a plurality of vertical cavity surface emitting laser diodes to the expanded surfaces of the pins;

3. bonding the vertical cavity surface emitting laser diodes to the other pins by conducting wires;

4. holding the frame on which the vertical cavity surface emitting laser diodes are mounted by a plurality of housings to complete the assembly of the vertical cavity surface emitting laser diodes, each housing having an opening, a notch and a mounting chamber; and

5. cutting off connected portions among the pins to obtain the vertical cavity surface emitting lasers.

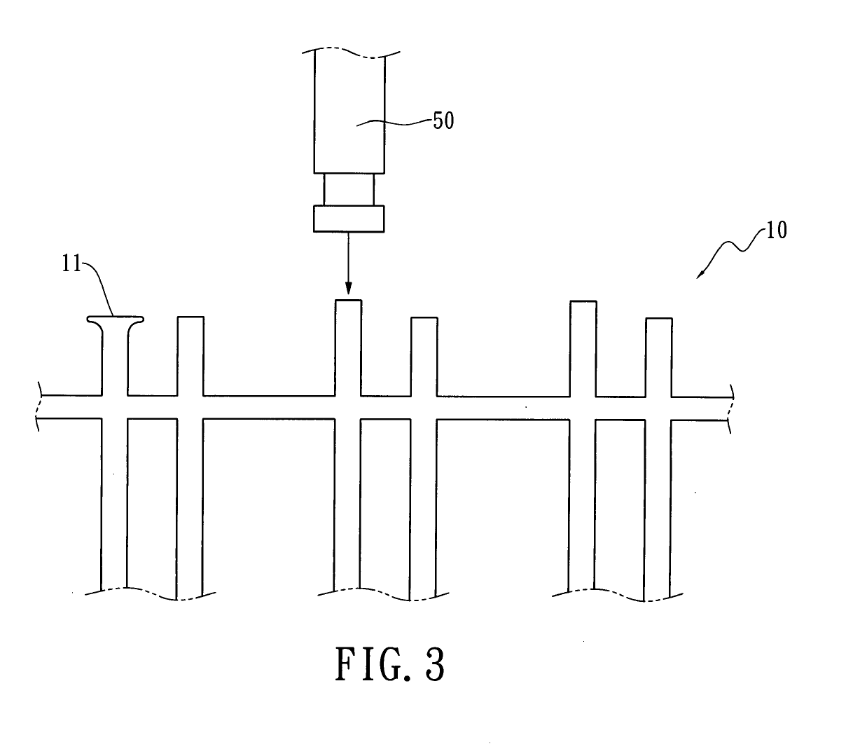

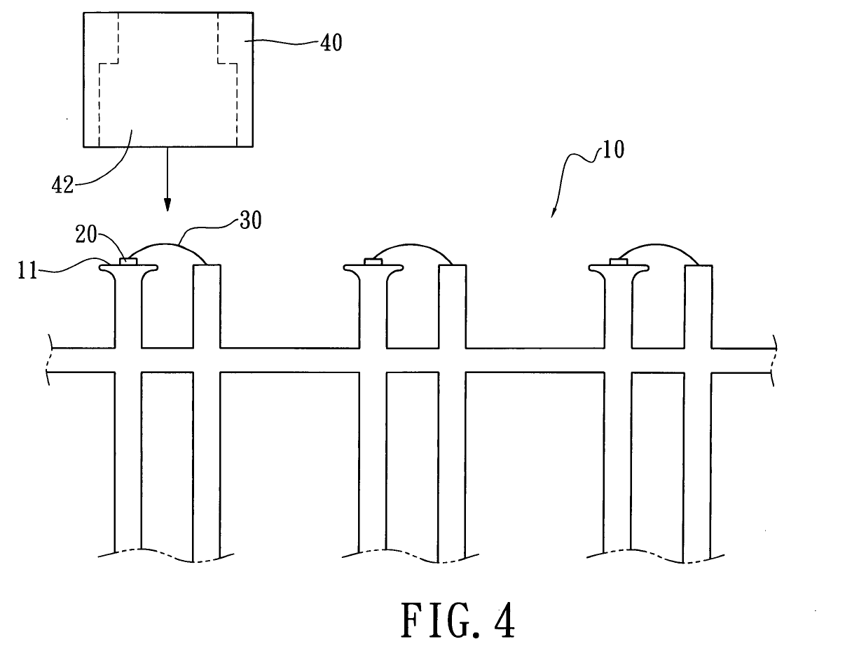

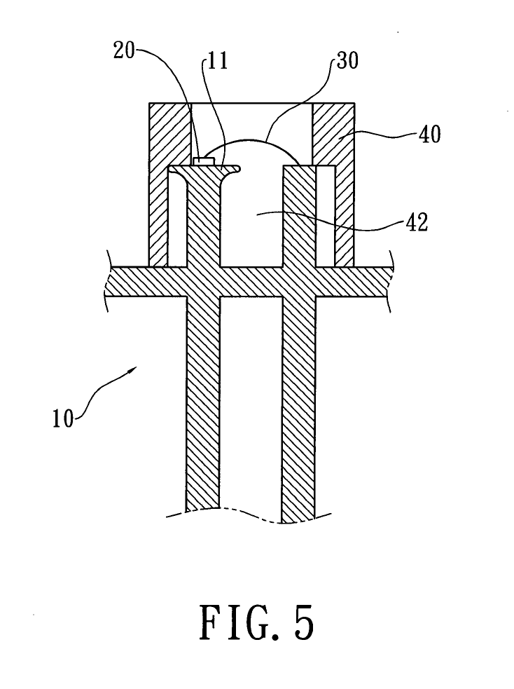

Referring to FIG. 3 through FIG. 5, in the practical manufacture process, a frame 10 on which a plurality of pin groups are mounted is provided, and the top ends of the higher pins of the pin groups are punched by a punch 50 for providing the punched pin with large-area expanded surfaces 11. Besides, the punched pins and the other pins are equal in height.

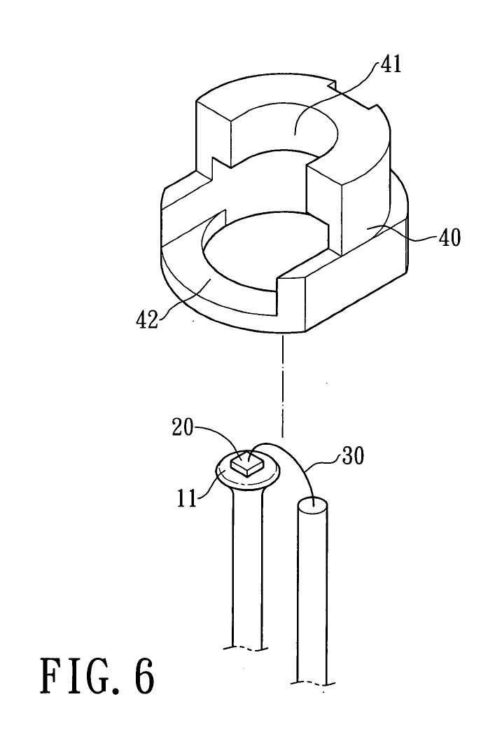

A plurality of vertical cavity surface emitting laser diodes 20 are connected to the expanded surfaces 11 of the pin groups by adhesive. The vertical cavity surface emitting laser diodes 20 are bonded to the other pins of the pin groups by conducting wires. As shown in FIG. 6, a housing 40 having an top opening 41, a side notch 42, and an inner mounting chamber is put to use for downward holding the top of each pin group and the vertical cavity surface emitting laser diode 20 such that the connection portion between the mounting chamber and the opening 41 is located against the expanded surface 11 of the pin and the edge of the other pin. Accordingly, the vertical cavity surface emitting laser diodes 20 are exposed through the openings 41 of the housings 40, and the assembly of the uncut vertical cavity surface emitting laser diodes is thus completed. After the uncut frame 10 and the connected portions among these pins are cut off numerous surface emitting lasers are obtained. Consequently, this manufacture method is suitable for mass production.

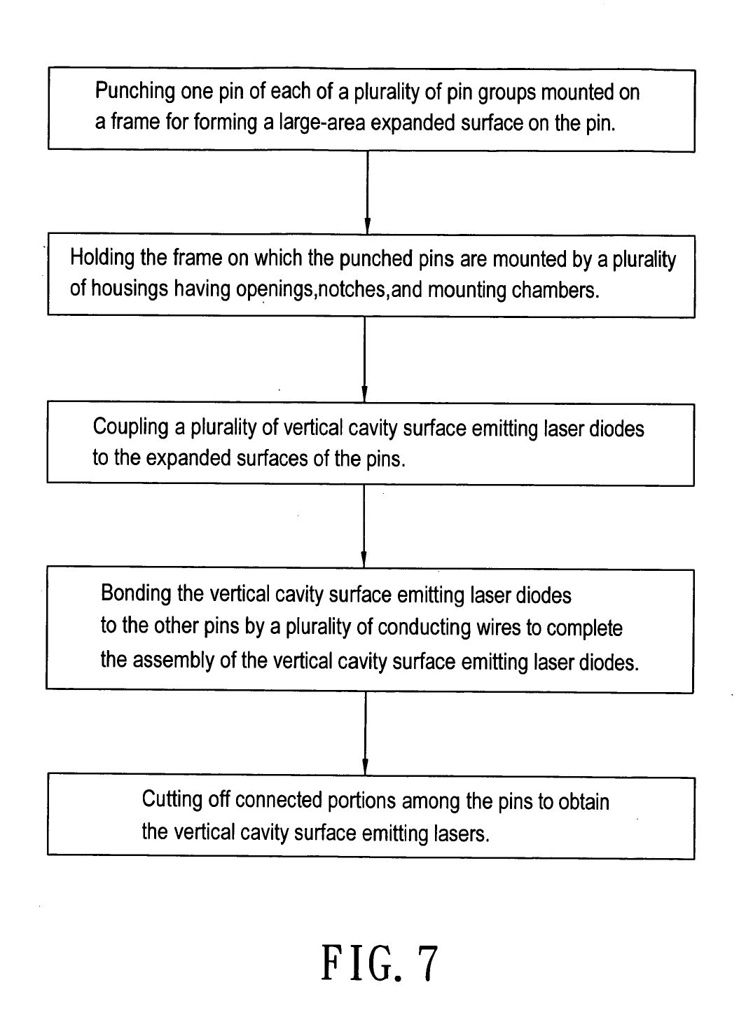

Referring to FIG. 7, another manufacture process of the present invention comprises the steps of:

1. punching one pin of each of a plurality of pin groups mounted on a frame for forming a large-area expanded surface on the pin;

2. holding the frame on which the punched pins are mounted by a plurality of housings, each having an opening, a notch and a mounting chamber;

3. coupling a plurality of vertical cavity surface emitting laser diodes to the expanded surfaces of the pins;

4. bonding the vertical cavity surface emitting laser diodes to the other pins by conducting wires to complete the assembly of the vertical cavity surface emitting laser diodes; and

5. cutting off connected portions among the pins to obtain the vertical cavity surface emitting lasers.

From the above-mentioned description it is apparent that the manufacture method of the present invention has the following advantages in which:

1. The higher pins mounted on the frame are punched directly by the punch for forming the large-area expanded surfaces on the tops of the punched pins, and therefore the drawbacks of the conventional technology in which numerous procedures are required are overcome efficiently.

2. The uncut frame is punched directly by the punch for forming the large-area expanded surfaces, which facilitates the connection of the laser diode, and therefore the production cost is significantly reduced.

3. The manufacture process of the present invention simplifies the assembly process of the base so it is fast and therefore suitable for mass production.

On the basis of the aforementioned description, the method of manufacturing the vertical cavity surface emitting laser of the present invention improves the deficiencies in the conventional manufacture method. Besides, the present invention provides the method of manufacturing the vertical cavity surface emitting laser for simplifying the manufacture process and reducing the production cost. The present invention satisfies all requirements for a patent and is submitted for a patent.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. A method of manufacturing a vertical cavity surface emitting laser comprising the steps of:
a. punching one pin of each of a plurality of pin groups mounted on a frame for forming a large-area expanded surface on the pin;
b. coupling a plurality of vertical cavity surface emitting laser diodes to the expanded surfaces of the pins;
c. bonding the vertical cavity surface emitting laser diodes to the other pins by conducting wires;
d. holding the frame on which the vertical cavity surface emitting laser diodes are mounted by a plurality of housings to complete the assembly of the vertical cavity surface emitting laser diodes, each housing having an opening, a notch and a mounting chamber; and
e. cutting off connected portions among the pins to obtain the vertical cavity surface emitting lasers.

2. A method of manufacturing a vertical cavity laser comprising the steps of:
a. punching one pin of each of a plurality of pin groups mounted on a frame for forming a large-area expanded surface on the pin;
b. holding the frame on which the punched pins are mounted by a plurality of housings, each having an opening, a notch and a mounting chamber;
c. coupling a plurality of vertical cavity surface emitting laser diodes to the expanded surfaces of the pins;
d. bonding the vertical cavity surface emitting laser diodes to the other pins by a plurality of conducting wires to complete the assembly of the vertical cavity surface emitting laser diodes; and
e. cutting off connected portions among the pins to obtain the vertical cavity surface emitting lasers.
